(19) United States
(12) Patent Application Publication
(10) Pub. No.: US 2014/0102888 A1
(43) Pub. Date: Apr. 17, 2014

(54) METHOD AND APPARATUS TO PRODUCE HIGH DENSITY OVERCOATS

(71) Applicant: Intevac, Inc., Santa Clara, CA (US)

(72) Inventors: Samuel D. Harkness, IV, Berkeley, CA (US); Terry Bluck, Santa Clara, CA (US); Michael A. Russak, Pleasanton, CA (US); Quang N. Tran, San Jose, CA (US); David Ward Brown, Pleasanton, CA (US)

(73) Assignee: Intevac, Inc., Santa Clara, CA (US)

(21) Appl. No.: 14/046,720

(22) Filed: Oct. 4, 2013

Related U.S. Application Data
(63) Continuation-in-part of application No. 13/094,779, filed on Apr. 26, 2011.
(60) Provisional application No. 61/424,550, filed on Dec. 17, 2010.

(51) Int. Cl. C23C 14/35

(52) U.S. Cl. CPC C23C 14/35
USPC 204/298.03; 204/298.16; 204/298.07

(57) ABSTRACT

A deposition system is provided, where conductive targets of similar composition are situated opposing each other. The system is aligned parallel with a substrate, which is located outside the resulting plasma that is largely confined between the two cathodes. A “plasma cage” is formed wherein the carbon atoms collide with accelerating electrons and get highly ionized. The electrons are trapped inside the plasma cage, while the ionized carbon atoms are deposited on the surface of the substrate. Since the electrons are confined to the plasma cage, no substrate damage or heating occurs. Additionally, argon atoms, which are used to ignite and sustain the plasma and to sputter carbon atoms from the target, do not reach the substrate, so as to avoid damaging the substrate.

### CROSS-REFERENCE TO RELATED APPLICATIONS

This application is a continuation-in-part of and claims priority benefit from U.S. application Ser. No. 13/094,779, filed Apr. 26, 2011, which claims priority from U.S. Provisional Application No. 61/424,550, filed on Dec. 17, 2010, the entirety of both which is incorporated herein by reference.

### BACKGROUND

1. Field

This application relates to the art of forming thin films, such as by physical vapor deposition (PVD). More specifically, this application relates to forming thin film, such as diamond-like coating (DLC) on substrates, such as magnetic disks used in hard drives.

2. Related Art

Hard drive disks are fabricated by forming various thin-film layers over a round substrate. Some of these layers include magnetic materials that is used as the memory medium, and some of these layers are formed as protection. Finally, a lubricant layer is deposited on the surface of the disk to enable smooth flying of the magnetic read/write head.

As recording densities intensify, new technologies have emerged to enable recording upon nanometer-sized granular medium designs. As always, thin but reliable tribological layers are sought, that provide a robust interface with the lubricant layer and a minimal detraction from reading/writing capabilities. Additionally, some in the industry seek a solution to writing very high anisotropy magnetic material (required to stabilize miniscule grains from random reversal due to thermal agitation) in the form of thermal assist. This is currently at the laboratory level, but the concept yields great promise for extending the limit of areal density well past 1 Tb/in².

One formidable obstacle to realizing this design in manufacturing is the reality that current hydrogenated diamond like carbon (DLC) overcoats are likely to become graphitized under the persistent exposure to elevated temperatures and, thus, lose their protective quality. Using current overcoat application paradigms (e.g., ion beam chemical vapor deposition (CVD)), however, it is required that hydrogen be added reactively to the growth process to pacify the high density of dangling bond defects incumbent in the processes. Many have considered filtered cathodic arc (FCA) as an alternative process capable of producing high density, high quality DLC films without the addition of process hydrogen.

With increasing film density toward the limit of 3.51 g/cm³ (sp³ diamond) comes the enhanced ability to reduce the overcoat from typical thicknesses of 3 nm to 2 nm without the sacrifice of increased exposure to corrosion. It is understood to be the high flux density of positively ionized carbon atoms at specific ranges of adsorption energy that enables the highly sp³-structured resultant film. Unfortunately, the FCA technique brings with it inherent problems including compatibility with the installed base of disc processing equipment, a process prone to high counts of particulates, and poor scalability to accommodate various sizes of substrates and carrier panels.

Consequently, a solution is required to enable fabrication of high quality sp³-structured DLC using a process that readily lands itself to commonly available disk manufacturing equipment.

### SUMMARY

The following summary of the invention is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

Various embodiments of the invention enable a new adaptation of an existing technology to deliver the same scope of benefits as reviewed for FCA overcoats (generally called ta-C films or tetrahedral amorphous carbon) without the listed liabilities.

Embodiments of the invention enable high deposition rate, high target utilization, controlled plasma interaction with the growing film, and reduced neutral recoil or negative ion induced damage on the substrate. The embodiments are useful for various applications, and are especially beneficial for depositing DLC coating. Other examples where embodiments of the invention can be beneficial include ITO (Indium Tin Oxide) deposition of polymeric substrates (OLEDs, etc.), high quality TCO (transparent conductive oxide with high transmissivity and low resistivity (T, ρ), such as ZnO:Al, ITO, etc., deposition of a-Si:H (hydrated amorphous silicon), improved CIGS/CIS sputter quality, Li/LiCoO3 deposition for improved Li-ion battery capacity, etc.

A deposition system is provided, where conductive targets of similar composition are situated opposing each other. The system is aligned parallel with a substrate, which is located outside the resulting plasma that is largely confined between the two cathodes. That is, embodiments of the invention generate a “plasma cage” wherein the carbon atoms collide with accelerating electrons and get highly ionized. The electrons are trapped inside the plasma cage, while the ionized carbon atoms are deposited on the surface of the substrate. Since the electrons are confined to the plasma cage, no substrate damage or heating occurs. Additionally, the embodiments are designed such that argon atoms, which are used to ignite and sustain the plasma and to sputter carbon atoms from the target, do not reach the substrate, so as to avoid damaging the substrate.

According to aspects of the invention, a facing target sputtering (FTS) has been developed to enable high arrival rates of ionized atoms to a substrate situated remotely from the plasma. In the application for depositing ta-C films, the highly ionized atoms are highly ionized carbon atoms. Specifically, a minimum of 30 eV adatom energy is believed to be required for sp³ formation. Therefore, embodiments of the invention are structured to deliver 30-100 eV adatom energy, wherein the optimal energy is 54 eV.

Embodiments of the invention enable the fabrication of DLC densities greater than 2.7 g/cm³ and without the incorporation of process hydrogen.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1 illustrates a system according to an embodiment of the invention;

FIG. 2 illustrates a cross section of one of chambers 140;

FIG. 3 is a simplified schematic illustrating a combination source according to an embodiment of the invention, viewed from inside of the chamber, as shown in broken-line arrows A-A in FIG. 2.

FIG. 4 is a plot of X-ray reflectometry (XRR) pattern for representative DLC film grown on a NiP/Al disc substrate. Fitting analysis results in the determination that this film is high density (˜2.9 g/cm3), with a thickness of 22 nm and a roughness conformal to the substrate below (<0.5 nm).

FIG. 5 is a top cut-away view illustrating an example of an FMS according to one embodiment.

FIG. 5A illustrates an embodiment wherein a single magnetron is used.

### DETAILED DESCRIPTION

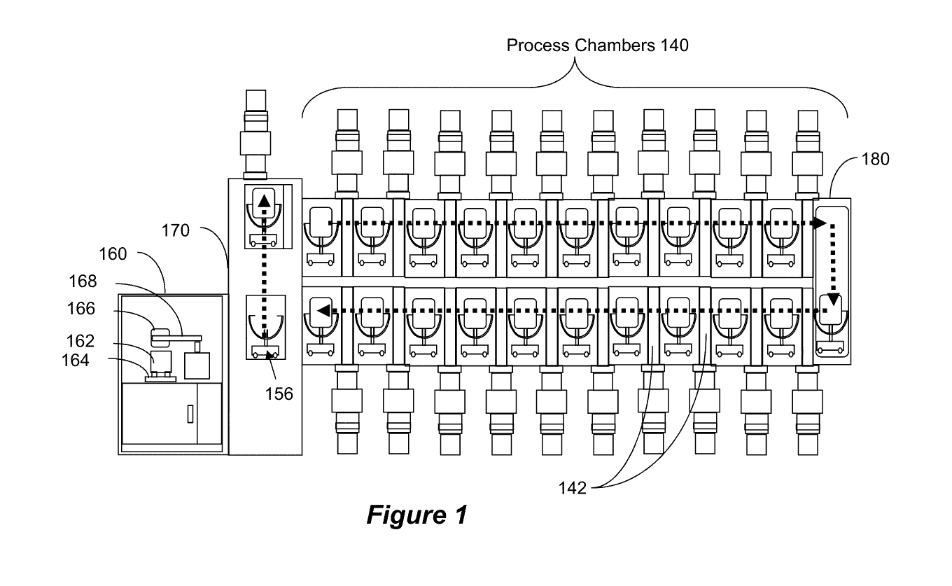

A detailed description will now be given of a processing system according to embodiments of the invention. FIG. 1 illustrates a system for high capacity sequential processing of substrates, which employs unique sputter deposition sources. The system is especially beneficial for fabrication of disks for hard disk drives, but can also be used for fabrication of other devices, such as solar cells, light emitting diodes, etc. In one embodiment, the invention is implemented on an Intevac 200 Lean™ disc-sputtering machine, available from Intevac of Santa Clara, Calif. The system is generally constructed of several identical processing chambers 140 connected in a linear fashion, such that substrates can be transferred directly from one chamber to the next. While in the embodiment of FIG. 1 two rows of chambers are stacked one on top of the other, this is not necessary, but it provides a reduced footprint.

A front end module 160 includes tracks 164 for transporting cassettes 162 containing a given number of substrates 166. The front end unit 160 maintains therein a clean atmospheric environment. A robotic arm 168 or other system (e.g., knife edge lifter) removes substrates 166, from the cassette 162 and transfers them into a loading module 170. Loading module 170 loads each substrate 166 onto a substrate carrier 156, and moves the substrate 166 and carrier 156 into a vacuum environment. According to another implementation, the loading module is already in vacuum environment, so that the loading of the substrate onto the carrier is done in vacuum environment.

In the embodiment of FIG. 1, each carrier is shown to hold a single substrate, but other embodiments can utilize carriers that hold two substrates, either in tandem or back to back. Thereafter the carriers 156 and substrates 166 traverse the processing chambers 140, each of which operates in vacuum and is isolated from other processing chambers by gate valves 142 during processing. The motion of the carrier 156 is shown by the broken-line arrows. Once processing is completed, the substrate 166 is removed from the carrier 156 and is moved to an atmospheric environment and placed in the cassette 162 by robot arm 168.

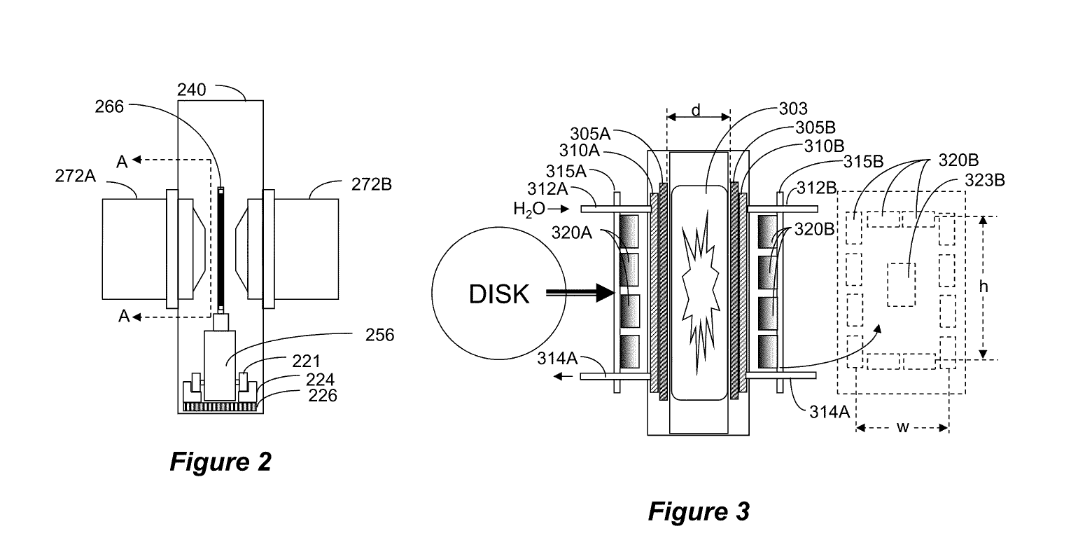

In FIG. 1, each of chambers 140 can be tailored to perform a specific process. For example, some chambers may be fitted with a heater to heat or anneal the substrate; some chambers may be fitted with standard sputtering source to deposit magnetic material on the surface of the substrate, etc. FIG. 2 illustrates a cross section of one of chambers 140 which is fitted with two sputtering sources 272A and 272B, according to an embodiment of the invention. Substrate 266 is shown mounted vertically onto carrier 256. Carrier 256 has wheels 221, which ride on tracks 224, but the reverse can also be implemented, i.e., the carrier may have tracks which ride on wheels situated in the chamber. The wheels 221 may be magnetic, in which case the tracks 224 may be made of paramagnetic material. In this embodiment the carrier is moved by linear motor 226, although other motive forces and/or arrangements may be used. Depositions source 272A is shown mounted onto one side of the chamber 240, while deposition source 272B is mounted on the other, opposite, side of the chamber. The carrier passes by deposition source 272, such that deposition is performed on the surface of the substrate as the substrate is moved passed the source.

FIG. 3 is a schematic illustration of one of sources 272A, 272B, as they appear looking head on from inside the chamber, as shown by arrows A-A in FIG. 2. In this arrangement, sputtering targets 305A, 305B, which in this example are comprised of conductive graphite, stand facially opposed each other at a separation distance “d” governed by the resultant magnetic field found in the mid-gap between the two. In this example, the targets abut heat sinks in the form of cooling plates 310A, 310B, in which cooling fluid, such as water, circulate.

Behind each target, a mounting plate, e.g., stainless steel plate 315A, 315B, is provided with magnets 320A, 320B. The magnets are arranged about the periphery of the mounting plate 315A, 315B, so that one of the magnetic pole is pointed towards the target. This can be seen more clearly from the phantom drawings shown in broken-line in FIG. 3. In FIG. 3, each magnet is shown shaded such that the darker side signifies a north magnetic pole and the lighter side signifies a south magnetic pole. In the example of FIG. 3, the magnets are arrange such that their magnetic pole is facing the target and is of opposite polarity of the corresponding magnet on the other target. That is, as can be seen in FIG. 3, magnets 320A have their lighter side, i.e., their south magnetic pole pointed towards target 305A, while the corresponding magnets 320B have their darker side, i.e., their north pole pointing towards target 305B.

Also, as shown in FIG. 3, according to embodiments of the invention, the magnets are arranged so as to define an axis height, h, and axis width, w, of the magnet array. The axis height and width are set such that the flattening factor is above 0.65. That is: flattening factor f=(h−w)/h, >0.65.

According to aspects of the invention, the separation “d” of the targets and the magnets' strength are selected according to a defined relationship so as to enable the formation of the desired film having the desired properties, especially density property. The separation distance “d” between the target pair is designed to be between 30 and 300 mm and preferably between 40 and 200 mm. The maximum magnet energy products for the individual magnets 320A, 320B, ranges between 200 kJ/m³<BHₘₐₓ<425 kJ/m³ and preferably 300 kJ/m³<BHₘₐₓ<400 kJ/m³, which yields an engineered electron orbit length of about one micron, sufficient for robust ionization. This combination of ranges has shown to enable the deposition of high quality DLC film.

The design of the embodiment described enables to maximize the cross section of ionizing electrons (for ionization of C, Ar, Kr, Ne, Xe, N₂, H₂, He, etc.) in the region between the sputter source and the substrate. In this way, subsequent films will be constructed primarily from an ionized carbon adsorbate, which, as previously described, promotes higher density DLC fabrication. Accordingly, it is within one's discretion whether they would optimize toward a nearer separation between targets and a lower magnetic field, or a wider separation and, potentially, a higher field. It is found in general, that collimation of the adsorbate engenders improved film quality as arriving atoms have a minimum of translational energy for incidences normal to the growth plane. With increasing translational energy, the adsorbing specie is capable of migrating across the film plane wherein it will likely find an energetically favorable sp² bonding opportunity thus rendering the film more graphitic. Therefore, one may choose a more narrow target-to-target spacing to provide better oblique collimation with the sacrifice in the form of a partial loss in deposition rate.

Some unforeseen advantages of the disclosed system arise in support of the novel capabilities discussed heretofore. Most importantly, the pressure of the working gas (e.g., Ar) required for plasma ignition is reduced by approximately one order of magnitude. Whereas standard balanced magnetron cathodes (e.g., an Intevac L-URMA™) requires approximately 1.0 Pa to generate a plasma, the cathode pair described in this disclosure needs only 0.1 Pa for ignition. This advantage is leveraged twofold: first by the increase in mean-free-path for the adsorbate specie and, hence, lower thermalization effect; and second, by the resulting decrease of working gas incorporated into the growing film.

Also of importance is the discovery that with the cathode design being such that the magnetic B-fields are largely tangential to the cathode, the resulting confinement of the electrons within the target space greatly reduces the plasma connection to the substrate. And since the substrate is then effectively remote of the working plasma, there is little to no heating of the substrate during deposition. This affords the process engineer greater luxury of process-design and specifically enables the decision to have heat present during growth or not. Most who optimize DLC growth for the recording media application tend toward lower substrate temperatures to inhibit translational mobility of adsorbing atoms. A follow on to this advantage of remote placement of substrate is a decreased sensitivity to vacuum environment. Because there is no perceptible plasma available in the vicinity of the substrate, there is a reduced concentration of free radicals adversely reacting with the growth specie(s) during the deposition. This has the generalized effect of improved economics through higher yields as fewer finished film structures are found to have contamination defects; and the ability to thereby relax costly standards of vacuum quality prior to production.

### Example I

In a first example, a plurality of 354 kJ/m³ magnets are placed upon a 410 stainless steel mounting plate, which is subsequently attached directly behind each target's heatsink. The outer ring of magnets all have the same polarity, and the opposite polarity to the magnet plate constructed for the opposing target. An optional field-bending magnet 323B is added at the center of the mounting plate, so as to bend the magnetic field generated by the outer ring of magnets 320B. This provides an improved confinement of the plasma. In this example, an equal or weaker magnet 323B (BHₘₐₓ≦354 kJ/m³) of opposite polarity of magnets 320B is interposed within the outer ring.

### Example II

A process to produce a viable magnetic recording disc has been developed, using the described magnetron. The process preceding the carbon overcoat step is generalized to include a series of front end cleaning operations and possible mechanical texturing in preparation for multilayer deposition, which is not particularly relevant to the method of the invention. Furthermore, it is assumed that the preceding steps occurring prior to carbon deposition include some combination of magnetic and non-magnetic materials (predominantly metals) and that the disc temperature heading into the carbon deposition station is in the range of 300-500 K. A ta-C carbon deposition then ensues with the cathode pairs (one about each side of the disc) such that each has a target pair separated by 50 mm, with peripheral magnets having north magnetic pole pointing towards the target and a center magnet having a south magnetic pole pointing towards the target. The target on the opposite side has the opposite magnetic arrangement, i.e., peripheral magnets having south magnetic pole pointing towards the target and a center magnet having a north magnetic pole pointing towards the target. The arrays are powered by 354 kJ/m³ NdFeB permanent magnets.

The substrate is initially located aft of the chamber centerline (of which the cathode pair(s) gap is co-located), such that it is not exposed to the sputtering. Prior to turning on the flow of argon, the chamber background pressure is <2×10⁻⁴ Pa. When the Ar-pressure is then stabilized at 0.1 Pa, the cathodes are powered on (by applying power P of between 250 and 3500 W) and the substrate begins to travel past the cathode aperture 303 to the fore of center position (as shown by the double-arrow in FIG. 3). The speed of travel is determined by the desired throughput of the overall system. This “scan” approach allows enhanced thickness uniformity for the final carbon film. When the substrate reaches the fore position, the power is turned off and the gas mass-flow-controllers (MFC) are closed allowing the chamber to regenerate the base condition for the next disc to be processed. The disc is then either exited from the system, or subjected to a further processing step to further condition the film surface. After removal from vacuum, the disc is then put through backend processing where it receives a thin lubricant layer, post-deposition polishing and flyability assurance testing.

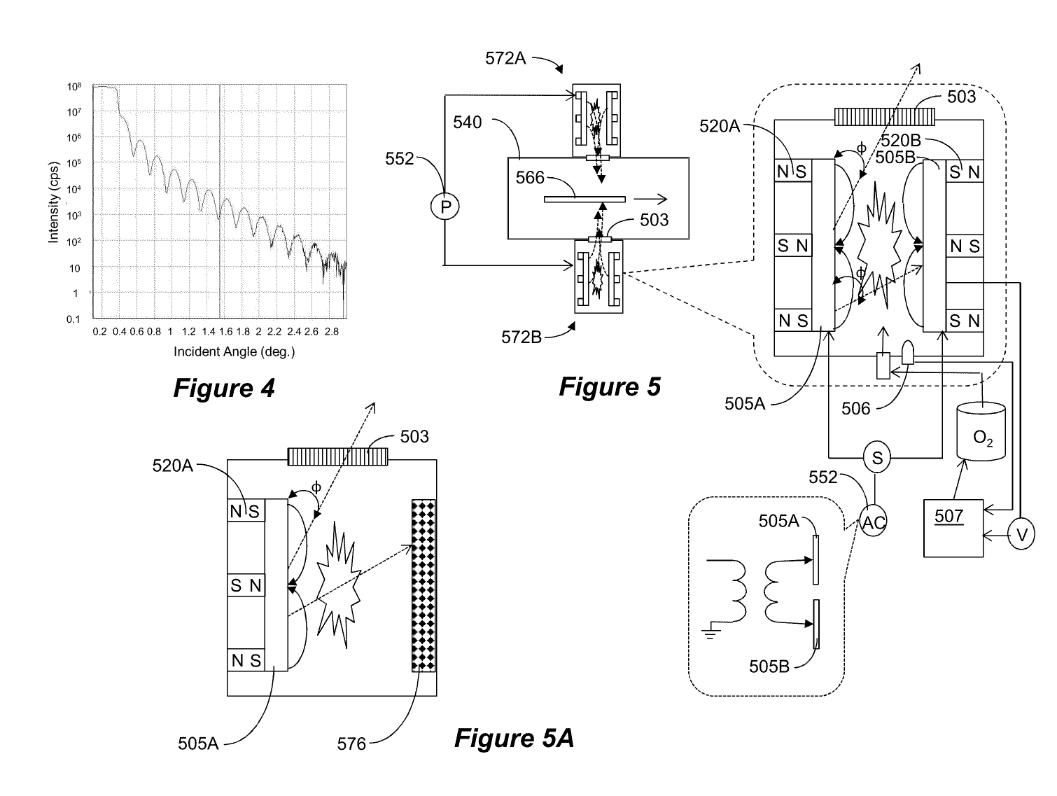

Shown in FIG. 4 is an x-ray reflectometry curve for a film grown in the abovementioned manner directly on a NiP/Al disc substrate. A fitting routines that combine known and unknown variables for the stack reveals a carbon film grown 22 nm thick, with a conformal roughness of 0.5 nm (the disc surface without carbon was also 0.5 nm), and a film density of 2.9 g/cm³. The competitive value of such a film would quickly be identified by one skilled in the art.

The resulting process carried out in the described apparatus provides high density carbon film (DLC) in the range of 2.4-3.5 g/cm³. In the described embodiments, the target and plasma are remote from the disk, so a highly ionized carbon atoms can be generated to result in high density carbon film. The magnetic field is lowered, thereby resulting in higher ionization cross-section. That is, the apparatus described herein uses remote plasma with low magnetic field to generate highly ionized carbon atoms. The facing targets as described confine the plasma. Low argon pressure can be used.

Although this disclosure is written specifically for the application of DLC films, the same technology would be of benefit to a wide variety of other materials including metals, ceramics, and semiconductors. The additional control of growth kinetics when a substantial portion of the adsorbate is in ionized form enables thin film synthesis with greater flexibility in process design.

The Facing Target Source (FTS), also referred to as Facing Cathode Source (FCS), disclosed above and shown in, for example, FIG. 3, has two sputtering targets positioned facing each other with an arrangement of magnets positioned in an orientation resulting in a magnetic field lines directed from one target to the opposite target. Electrons liberated from one target/cathode are repelled back and forth between the negatively biased cathodes, trapped on the field lines, thus creating an unusually high density plasma which is useful for some deposition processes.

As a result of the facing target geometry, reactive DC deposition of non-conductive coatings is severely limited by rapid buildup of nonconductive material on internal conductive anode/ground surfaces, required for plasma operation. As the nonconductive coating on the anode quickly becomes thicker and more continuous, electrons can't easily reach the grounded anode, resulting in arcs that become larger and more frequent, thereby leading to lower deposition rate, inclusion of particles in the coating, and leading to the inability to run the source usefully at all. Also, coating uniformity is adversely affected as the plasma shape changes in response to ground surfaces outside the source becoming the only available anode surfaces.

In the closely related deposition technology of magnetron deposition, a similar problem occurs and is referred to as the “disappearing” anode problem. The disappearing anode problem in an FTS is much more severe and happens much faster because the targets face each other, thus depositing directly, at high rate, on anode regions surrounding the opposite target. In magnetron sputtering, the targets face the substrate not each other, so that the coating that reaches the surrounding anode is not direct deposition from another target, but instead from a relatively much slower deposition, often called redeposition, of a small fraction of sputtered atoms which scatter off of gas molecules and the substrate surface, and are reflected back to the target and surrounding anode surfaces. Methods to counteract the disappearing anode in magnetron sputtering are well known. The most common are the Hidden Anode, and Dual Magnetron.

The Hidden Anode refers to anode designs with features that hide grounded areas of the anode from the nonconductive redepostion but still allow electrons to easily reach these hidden conductive anode areas. These hidden areas eventually become nonconductive but at a slow enough rate for useful production maintenance cycles. Although somewhat effective for a FTS, the improvement does not last long enough due to the higher rate direct deposition from the opposite target.

The Dual Magnetron Solution requires magnetrons to be used in pairs. Each pair is powered with a single AC supply, typically 40 kHz, such that one target is positive when the other is negative. When negatively biased the target sputters, while when positively biased it acts as the preferential anode for the other target—the required anode is supplied by the opposite target which stays clean and conductive due to the sputtering in the prior cycle. An FTS has two targets but because of the intrinsic design, a traditional FTS cannot be powered with AC because the magnetic field that confines the FTS plasma is very different from that of a magnetron. Both FTS targets are required to be negative. AC power as described will not create plasma in an FTS source.

What is needed is a source that provides the benefits of a traditional FTS source for conductive coatings but does not suffer severely from the disappearing anode when reactively depositing nonconductive, i.e. dielectric insulating coatings.

We have found unexpectedly that replacing the FTS magnetic field with a magnetron magnetic field provides coating property benefits previously touted for the traditional FTS. We refer to this source as a Facing Magnetron Source (FMS). Furthermore, the source is capable of being run with AC power, providing extended operation for nonconductive coating deposition without disruption due to a disappearing anode. FIG. 5 is a top cut-away view illustrating an example of an FMS according to one embodiment. Chamber 540 comprises a vacuum enclosure in which substrate 566 is transported along a linear track, as shown by the arrow. Chamber 540 has a vacuum enclosure having one or more openings for attaching one or more sputtering sources. The sputtering sources are bolted onto the exterior of the sputtering chamber wall, such that they provide sputtering particles via apertures positioned to correspond to the openings in the chamber vacuum enclosure. In the example of FIG. 5, sputtering deposition is performed on both sides of the substrate simultaneously, so that two sputtering sources 572A and 572B are mounted, one on each side of the chamber's exterior sidewall enclosure. If only one side of the substrate needs to be coated, one of the sputtering sources can be eliminated.

As shown in the broken-line callout of FIG. 5, each of the magnetron sputtering sources comprises a vacuum enclosure separate from the vacuum enclosure of the chamber, and the plasma is maintain completely within the vacuum enclosure of the sputtering source, confined between the two targets. An aperture 503—which may or may not be collimating—is provided in an orientation corresponding to the opening in the chamber sidewall, enabling gas and particle flow communication between the chamber vacuum enclosure and the sputtering source vacuum enclosure, although the plasma remains confined to the source's enclosure only. As will be elaborated more below, the aperture 503 is structured such that only particles emitted from the targets at a sharply acute angle φ reach the substrate 566. The aperture 503 may be a collimating aperture, e.g., it may include louvers that allow particles to traverse the aperture in a narrow range of angles. On the other hand, particles that are emitted from the target at a wide or normal angle φ will not exit through the aperture 503 and may be collected on the opposing target. The benefit of this arrangement is that particles that are emitted at a sharply acute angle are much less energetic than those that are emitted at a blunt or right angle. Therefore, particles that reach the substrate are of lower energy and do not cause any damage to the target. Also, using lower energy particles leads to a much more uniform coating of the substrate, since it avoids re-sputtering cause by high energy particles.

Unlike standard facing target arrangement, in the embodiment of FIG. 5 the magnet arrays 520A and 520B are arranged such that they mirror each other from one target to the other. For example, for each magnet having its north pole facing the target and its south pole facing away from the target, the corresponding magnet on the complimentary facing target also has its north pole facing the target and its south pole facing away from the target. This means that unlike conventional facing target arrangements, there are no magnetic field lines flowing between the facing targets. Rather, each magnet arrangement forms magnetic field lines that are confined to the corresponding target and do not flow to the other facing target. Thus, in essence, each target operates independently of the other.

As shown, the plasma is maintained between the two targets 505A and 505B. The two facing magnetrons are operated such that only one facing target sputters at a time, and any particles emitted at blunt or right angle collect on the opposite target. Then, when the operation switches and the other target starts to sputter, the collected particles would be sputtered away. Thus, build-up of particles on any target is avoided. Moreover, in some processes oxygen gas is provided into the chamber to form an oxidized coating, such as, e.g., SiO2. The collection of SiO2 on one target may “poison” the target and prevent further sputtering from that target. To prevent such poisoning, a controller 507 is used to control the flow of oxygen gas into the chamber. The controller may receive an optical signal from sensor 506, indicating the color and/or intensity of the plasma and thereby the conductivity of the target. A reduction in the conductivity of the targets changes the color and/or intensity of the plasma and indirectly signifies the buildup of SiO2 on one or both targets. The controller would then reduce the flow of O2 gas until the SiO2 buildup has been sputtered away from the surface of the target. Another embodiment is the use of voltage measurement, which also indicates the resistivity of the target and can signify buildup of SiO2 on a target's surface. Conversely, low resistivity (or high conductivity) of the target can signify the need to increase the flow of oxygen in order to form the proper oxidized particles for deposition of the proper insulating film.

The magnetrons are energized by an AC source. As shown in the dotted-line callout of FIG. 5, in this embodiment the targets are energized by an isolated AC source. That is, the AC potential applied to the magnetrons is not directly connected to the ground potential of the system. This can be achieved by, for example, using an isolating transformer. Also, the circled-S in FIG. 5 indicates that the AC power is applied to the magnetrons in an alternating manner, such that when one magnetron sputters, the target of the facing magnetron does not sputter and forms the ground potential to that sputtering magnetron, and vice versa.

As is well known, conventional facing target magnetrons must operate in tandem—using two targets with magnetic field lines traversing the two targets. Conversely, since in the embodiment of FIG. 5 the magnet arrangement is such that no magnetic field lines flow between the two targets, the two magnetrons can operate independently. In fact, rather than using two targets, one may use only a single target. FIG. 5A illustrates an embodiment wherein a single magnetron is used. In FIG. 5A the sputtering source vacuum enclosure houses a single magnetron with a single target 505A. A magnet array 520A is provided behind the target to enable independent operation of the magnetron. A particle collection shield 576 is provided inside the sputtering source vacuum enclosure and is positioned to orthogonally face the target 505A. The particle collection shield may be made of, e.g., aluminum, Al—Si alloy, and any other material that may collect carbon particles or other particles that are sputtered from the surface of target 505A. The surface of the particle collection shield 576 may be made rough, such that particle may adhere to the surface. Thus, particles that are emitted at a sharply acute angle from the target's 505A surface would pass through the aperture 503 and land on the substrate, while particles that are emitted at a blunt or right angle would be collected by the particle collection shield 576.

The present invention has been described in relation to particular examples, which are intended in all respects to be illustrative rather than restrictive. Those skilled in the art will appreciate that many different combinations of hardware, software, and firmware will be suitable for practicing the present invention. Moreover, other implementations of the invention will be apparent to those skilled in the art from consideration of the specification and practice of the invention disclosed herein. Various aspects and/or components of the described embodiments may be used singly or in any combination in the server arts. It is intended that the specification and examples be considered as exemplary only, with a true scope and spirit of the invention being indicated by the following claims.

1. A sputtering source comprising:
a vacuum chamber having provisions for mounting onto a processing chamber and having an ion emission aperture;
a first magnetron having a first sputtering target provided within the chamber and positioned such that its sputtering surface is oriented orthogonally to the aperture, such that only particle emitted from the first sputtering target at a sharply acute angle can exit through the aperture;
a second magnetron having a second sputtering target provided within the chamber and positioned such that its sputtering surface is oriented orthogonally to the aperture and in a parallel facing relationship to the first target and at a distance d from the first target, such that only particle emitted from the second sputtering target at a sharply acute angle can exit through the aperture;
a plasma power applicator coupling power to the first and second magnetrons for igniting and sustaining plasma within the vacuum chamber confined in the space between the first target and the second target;
a first magnet array positioned behind the first target, wherein a subset of magnets from the first magnet array are oriented with the south pole pointing towards the first target;
a second magnet array positioned behind the second target and positioned as a mirror image of the first array, such that magnets positioned behind the second target in a positioned directly across the subset of magnets are oriented with the south pole pointing towards the second target.

2. The sputtering source of claim 1, wherein the plasma power applicator comprises an isolated AC source having no direct connection to ground potential.

3. The sputtering source of claim 2, wherein the isolated AC source applied power alternatingly to the first and second magnetrons.

4. The sputtering source of claim 2, wherein the isolated AC source comprises an isolation transformer.

5. The sputtering source of claim 1, further comprising an oxygen gas injector controlled by a controller, wherein the controller controls the amount of oxygen gas delivered to the vacuum chamber by monitoring the resistivity of the first and second targets.

6. The sputtering source of claim 5, further comprising an optical sensor and wherein the controller monitors the resistivity of the first and second targets by monitoring the signal from the optical sensor.

7. The sputtering source of claim 5, further comprising a voltage sensor and wherein the controller monitors the resistivity of the first and second targets by monitoring the signal from the voltage sensor.

8. A deposition system for depositing a layer onto a substrate, comprising:
a processing chamber comprising a processing enclosure having an opening on a sidewall thereof and having provisions for linearly transporting the substrate inside the processing enclosure;
a sputtering source comprising a vacuum enclosure mounted onto exterior of the sidewall, the vacuum enclosure having an aperture corresponding to the opening on the sidewall, the sputtering source further comprising:
a first magnetron having a first sputtering target provided within the vacuum chamber and positioned such that its sputtering surface is oriented orthogonally to the aperture, such that only particle emitted from the first sputtering target at an acute angle can exit through the aperture, and a first magnet array positioned behind the first target, wherein a subset of magnets from the first magnet array are oriented with the south pole pointing towards the first target;
a second magnetron having a second sputtering target provided within the vacuum chamber and positioned such that its sputtering surface is oriented orthogonally to the aperture and in a parallel facing relationship to the first target and at a distance d from the first target, such that only particle emitted from the second sputtering target at an acute angle can exit through the aperture, and a second magnet array positioned behind the second target and positioned as a mirror image of the first array, such that magnets positioned behind the second target in a positioned directly across the subset of magnets are oriented with the south pole pointing towards the second target;
a plasma power applicator coupling power to the first and second magnetrons for igniting and sustaining plasma within the vacuum chamber confined in the space between the first target and the second targets
a transport mechanism provided within the processing chamber to scan the substrate while the first and second sputtering sources are energized.

9. The system of claim 8, wherein the transport mechanism transports the substrate in a linear direction in front of the aperture.

10. The system of claim 9, wherein the aperture is a collimating aperture.

11. The system of claim 8, wherein the plasma power applicator comprises an isolated AC source having no direct connection to ground potential.

12. The system of claim 11, wherein the isolated AC source applied power alternatingly to the first and second magnetrons.

13. The system of claim 11, wherein the isolated AC source comprises an isolation transformer.

14. The system of claim 8, further comprising an oxygen gas injector controlled by a controller, wherein the controller controls the amount of oxygen gas delivered to the vacuum chamber by monitoring the resistivity of the first and second targets.

15. The sputtering source of claim 14, further comprising an optical sensor and wherein the controller monitors the resistivity of the first and second targets by monitoring the signal from the optical sensor.

16. The sputtering source of claim 5, further comprising a voltage sensor and wherein the controller monitors the resistivity of the first and second targets by monitoring the signal from the voltage sensor.

17. The system of claim 8, further comprising a second sputtering source comprising a second vacuum enclosure mounted onto exterior of an opposite sidewall.
